(19) United States
(12) Patent Application Publication
(10) Pub. No.: US 2014/0264647 A1
(43) Pub. Date: Sep. 18, 2014

(54) METHOD OF FORMING MONOLITHIC CMOS-MEMS HYBRID INTEGRATED, PACKAGED STRUCTURES

(71) Applicants: Rakesh Katragadda, Ann Arbor, MI (US); Ganapathy Krishna Kumar, Troy, MI (US); Manveen Saluja, Troy, MI (US)

(72) Inventors: Rakesh Katragadda, Ann Arbor, MI (US); Ganapathy Krishna Kumar, Troy, MI (US); Manveen Saluja, Troy, MI (US)

(21) Appl. No.: 13/834,303

(22) Filed: Mar. 15, 2013

(51) Int. Cl. B81C 1/00; B81B 3/00

(52) U.S. Cl. CPC B81C 1/00134; B81B 3/0018
USPC 257/415; 438/51

(57) ABSTRACT

A method of forming a monolithic CMOS-MEMS hybrid integrated, packaged device comprising the steps of: providing a semiconductor substrate; forming MEMS or NEMS materials on the substrate having conductive, structural, or dielectric layers; forming at least one opening(s) on the semiconductor substrate; positioning on the substrate at least one prefabricated MEMS, NEMS, or semiconductor chip(s), wherein the chip(s) comprise a side facing the substrate; applying at least one filler material(s) in the opening(s) on the semiconductor substrate; applying at least one metallization layer electrically connecting chip(s) to the MEMS or NEMS materials; and performing at least one micro or nano fabrication etching step to remove a portion of the MEMS or NEMS materials.

### FIELD OF THE INVENTION

The invention relates to a method for integrating MEMS and CMOS structures.

### BACKGROUND OF THE INVENTION

Monolithic integration of MEMS/NEMS and electronics offers significant benefits enabling high volume production driving down the per-unit costs of sensor and actuator systems significantly. Micromechanical transducer systems not only need to receive analog and digital electrical inputs and transmit the output, but should also be able to measure rotation, strain, temperature, pressure, acceleration, infrared radiation, micro fluidic chemical properties of liquids and gasses. Effective integration offers other benefits, including, simplifying interconnect issues, reduced packaging and fabrication complexity and significantly improving the overall performance and ease of use for the device.

### SUMMARY OF THE INVENTION

In one embodiment, the method of forming a monolithic CMOS-MEMS hybrid integrated, packaged device comprises the steps of: providing a semiconductor substrate; forming MEMS or NEMS materials on the substrate having conductive, structural, or dielectric layers; forming at least one opening(s) on the semiconductor substrate; positioning on the substrate at least one prefabricated MEMS, NEMS, or semiconductor chip(s), wherein the chip(s) comprise a side facing the substrate; applying at least one filler material(s) in the opening(s) on the semiconductor substrate; applying at least one metallization layer electrically connecting chip(s) to the MEMS or NEMS materials; and performing at least one micro or nano fabrication etching step to remove a portion of the MEMS or NEMS materials.

Providing a semiconductor substrate comprises single crystal silicon or Silicon on Insulator (SOI) wafers used in the fabrication of integrated circuits or microsystems. These wafers serve as substrates that undergo micro or nano fabrication process steps for both CMOS control, signal processing circuits, MEMS or NEMS sensing elements, or the like.

Forming MEMS or NEMS materials on the substrate having conductive, structural, or dielectric layers comprises process steps such as doping, annealing at high temperatures, wet or dry etching, deposition of materials in vacuum, photolithographic patterning using micro or nanofabrication process steps, or the like.

The MEMS or NEMS materials can be the following structures: accelerometers, resonators, micro-gyroscopes, microphones, micro-bolometers, transducers involving chemical and biological properties, optical sensors, mechanical sensors, radiation sensors, thermal sensors, capacitive sensors, rotation sensors, strain sensors, magnetic and electromagnetic sensors, flow sensors, sensors for micro-fluidic chemical properties of liquids and gases, or the like.

The structural layer can be polysilicon with a conductive area which is doped and annealed. Polysilicon can be deposited using low-pressure chemical-vapor deposition at very high temperatures in the range of 570 deg C. to 620 deg C. and is heavily doped to form a p-type or n-type layer.

An opening can be formed with Deep Reactive Ion Etching (DRIE) to create high aspect ratio trenches in the semiconductor substrate.

The prefabricated MEMS, NEMS, or semiconductor chip can be CMOS integrated circuits, electronics, amplifier dies, analog to digital converters, Radio Frequency (RF) circuits, optical chips, memory, power management circuits, GaAs chips, passive components, MEMS or NEMS sensors, MEMS or NEMS dies, or the like.

The filler layer can be constructed of epoxies, polyimides, SU8, polymers, or the like for attaching the chip(s) to the substrate with applications used for epoxy die attachments such as simple transistors, LED attachments, hybrids, or the like.

The MEMS or NEMS dies can be accelerometers, resonators, micro-gyroscopes, microphones, micro-bolometers, transducers involving chemical and biological properties, optical sensors, mechanical sensors, radiation sensors, thermal sensors, capacitive sensors, rotation sensors, strain sensors, magnetic and electromagnetic sensors, flow sensors, sensors for micro-fluidic chemical properties of liquids and gases, or the like.

The metallization layer can be evaporated, sputtered or electroplated and can be aluminum, titanium, chrome, gold or platinum, a combination of the same, or the like.

The micro or nano fabrication etching step can be wet, dry, isotropic, anisotropic etching, or the like.

Forming at least one opening(s) on the semiconductor substrate; positioning on the substrate at least one prefabricated MEMS, NEMS, or semiconductor chip(s), wherein the chip(s) with a side facing the substrate comprises using automated component placement system in high-mix, low-volume precision microelectronics assembly to precisely place within a few microns margin of error, the chip inside the high aspect ratio DRIE trench. A controlled downward force on the pick and place tool is used to ensure optimal handling of fragile semiconductor chips.

Applying at least one filler material(s) in the opening(s) on the semiconductor substrate comprises a low viscosity epoxy that is dispensed on top of the chip. The encapsulant flows and conforms to the shape of the chip.

Applying at least one metallization layer electrically connecting chip(s) to the MEMS or NEMS materials comprises depositing Aluminum, Gold, Titanium using evaporation or sputter techniques or electroplating process.

Performing at least one micro or nano fabrication etching step to remove a portion of the MEMS or NEMS materials comprises dissolution of a material in a chemical compound known as wet etching or dissolution using a vapor phase compound known as dry etching.

The scope of the invention is defined by the claims, which are incorporated into this section by reference. A more complete understanding of embodiments on the present disclosure will be afforded to those skilled in the art, as well as the realization of additional advantages thereof, by consideration of the following detailed description of one or more embodiments. Reference will be made to the appended sheets of drawings that will first be described briefly.

The following detailed description of the invention is merely exemplary in nature and is not intended to limit the invention or the application and uses of the invention. Furthermore, there is no intention to be bound by any theory presented in the preceding background of the invention or the following detailed description of the invention.

### BRIEF DESCRIPTION OF THE DRAWINGS

FIG. 1 is Prior Art showing cross-section of the embedded micromechanics approach to CMOS/MEMS integration from Sandia National labs.

FIG. 2 is Prior Art showing simplified cross-sectional view of HDI interconnect MCM technology from GE.

FIG. 3 is a cross-sectional view showing the first step of an embodiment of the method for building a monolithic CMOS-MEMS hybrid integration system and packaging.

FIG. 4 is a cross-sectional view showing the second step of an embodiment of the method for building a monolithic CMOS-MEMS hybrid integration system and packaging.

FIG. 5 is a cross-sectional view showing the third step of an embodiment of the method for building a monolithic CMOS-MEMS hybrid integration system and packaging.

FIG. 6 is a cross-sectional view showing the fourth step of an embodiment of the method for building a monolithic CMOS-MEMS hybrid integration system and packaging.

FIG. 7 is a cross-sectional view showing the fifth step of an embodiment of the method for building a monolithic CMOS-MEMS hybrid integration system and packaging.

FIG. 8 is a cross-sectional view showing the sixth step of an embodiment of the method for building a monolithic CMOS-MEMS hybrid integration system and packaging.

### DETAILED DESCRIPTION OF THE PREFERRED EMBODIMENTS

One method of monolithic integration of CMOS and MEMS is to modify the complementary metal-oxide semiconductor (CMOS) foundry facility to fabricate micromechanical structures. Some of the commonly used micromechanical (MEMS) mechanical structures like polysilicon, nitride, etc. require high-temperature processing during deposition and annealing to relieve stress and this cannot be performed on the same substrate in the presence of CMOS electronics due to the lower temperature limitation of the metals in CMOS.

Another limitation of the method is that CMOS requires the substrate to be planar after the MEMS fabrication to achieve high-resolution features in the photolithographic process. Thus, the current CMOS-MEMS integration methodologies faces serious limitations, requiring sacrificing materials and allowing very little flexibility in device design.

Monolithic integration process may be divided into three classes: (1) Pre CMOS (2) Intermediate CMOS (3) Post CMOS. In prior art “pre CMOS” fabrication process methods, MEMS/NEMS structures are fabricated before the electronics are integrated. One example of this process is the micromechanics-first approach developed at Sandia National Laboratory by J. Smith et al. In this process a pre-etched trench is used to house the MEMS structures. After the fabrication of the desired MEMS structures, this housing is refilled with oxide, planarized using chemical-mechanical polishing (CMP), and finally sealed with a nitride membrane. Conventional CMOS processing was then carried out next to this MEMS area. This defined a CMOS device area and micromechanical device area on the same substrate as shown in FIG. 1. One of the disadvantages with this process is that it needs a dedicated production line and the process is complicated.

In the Intermediate CMOS fabrication process, the process flow between CMOS and MEMS is mixed in the sequence. Initially a part of the CMOS process is performed and then paused for additional thin film deposition or micromachining steps. Some of the commercially available sensors in this art include the Analog Devices integrated MEMS and Infineon's pressure sensor shown by C. Hierold. In the post CMOS process, MEMS/NEMS structures are fabricated after the CMOS or electronics is fabricated on the substrate. The disadvantage of this process is the temperature limitation of the process to below 400° C. to protect the aluminum in the electronics. This leads to the elimination of commonly used MEMS/NEMS high temperature materials like LPCVD polysilicon, silicon nitride etc.

An alternative approach to integration and packaging using high density interconnect (HDI) multichip modules (MCMs) was developed by researchers at GE Corporate Research and Development center as a “chips first” approach described in by W. Daum et al. as shown in FIG. 2. This process involves placing bare chips of MEMS test die and a generic CMOS electronics die into mechanically milled cavities on a base substrate and then fabricating the thin-film interconnect structure on top of the components. A computer-controlled argon ion laser system drills via holes through the polyimide film directly to the chip I/O pads. The interconnection metallization and via contacts were formed by a combined sputtering/electroplating process and patterned by computer-controlled adaptive laser lithography and etching. Some of the limitations with this process were the warping of the MEMS device due to excessive heating during the laser ablation step.

Prior art monolithic integration processes in this art involve utilizing complimentary metal-oxide semiconductor (CMOS) semiconductor layers to fabricate micromechanical structures is shown in U.S. Pat. No. 5,717,631, U.S. patent application Ser. No. 11/602,087, U.S. Pat. No. 6,060,336. Some of the major limitations with this approach involve the need to sacrifice MEMS/NEMS materials with various mechanical properties as commercial foundries cannot modify their processes to suit MEMS/NEMS. This also adds additional constraints when fabricating the MEMS/NEMS sensors or actuators as they would need to limit their processing techniques like etching, deposition so as to not harm the electronic circuits present on the substrate. Stress and other mechanical deficiencies may lead to device failure when the materials tailored to CMOS are modified as mechanical elements in MEMS.

Prior art hybrid MCM technology processes include putting one or several dies with different functionality into prefabricated trenches on a substrate, planarizing these chips, providing an insulator layer on top and forming electrodes have been demonstrated in U.S. Pat. No. 6,403,463, U.S. Pat. No. 6,780,696 B1, U.S. Pat. No. 6,154,366, U.S. Pat. No. 6,759,270. Some of the major drawbacks in these prior art references include semiconductor substrates like silicon that are fragile and the devices need to be repackaged resulting in significant costs.

The invention describes a method of manufacture for Monolithic hybrid integration of CMOS-MEMS with enhanced flexibility of using materials without hindrance to process parameters. This invention enables this integration effectively without the need to sacrifice the inherent strengths of both the CMOS or MEMS technologies and bringing about their fusion in a hybrid approach on a common substrate. This invention also allows the ability to effectively package the entire system after integration.

Several of the limitations mentioned above are overcome in the present invention which describes a method to effectively synergize CMOS-MEMS/NEMS functionality and finally package them creating a very cost effective, reliable, robust transduction system In the present invention, protective layers are coated on the substrate to protect either the CMOS device area in the “Post CMOS” process or the MEMS device area in the “Pre CMOS” process to prevent damage to the sensor or electronics. Oxygen plasma etching can be used to open the vias to access conductive layers, being precisely defined by photolithography instead of laser which is known to cause damage in some of the previous integration approaches.

Either the “Post CMOS” or “Pre CMOS” fabrication may be carried out on a semiconductor substrate without compromising on the individual technologies strength and then integrating CMOS if MEMS is already present or MEMS if CMOS is already present on the same substrate.

The invention provides an improved ability to effectively package an entire system using a glass, silicon, plastic or metal housing. Packaging provides physical protection against external scratching and breakage, environmental protection and any other external forces that may damage the leads or the sensors. Effective packaging of the integrated system leads to lower cost, improved reliability and improved performance. This invention addresses some of the important issues present in current packaging methodologies. As one specific example related to reliability issues with plastic packages, the Thermal coefficient of expansion (TCE) mismatch resulting from the curing of the resins as they shrink in volume, creates a large temperature differential resulting in large strain mismatch, damaging the wire bonds. This issue can be eliminated or reduced significantly in the present invention as there will be no wire bonds involved and the fabrication is planar and the metal traces can be more effectively protected. The packaging methodology from the current invention also eliminates the need for solder bumps for integration of CMOS-MEMS and packaging. The invention also provides a method to further encapsulate the entire system by adding a secondary protective layer of organic materials providing a very effective packaging methodology.

Referring to the various Figures there is shown an effective, reliable, and relatively low cost method of integration between CMOS-MEMS/NEMS.

Referring to FIG. 3 there is shown a first step including providing a substrate 102 that may be a semi-conductor insulator as described above. The substrate 102 may include MEMS/NEMS materials 105 applied thereon. In one aspect, the MEMS/NEMS material 105 that can be made conductive include high temperature MEMS materials such as LPCVD polysilicon that can be later doped in boron or phosphorous and or may also include LPCVD nitride and or metals such as aluminum, copper, titanium, chrome, gold, silver, iridium or their combination that can be evaporated, sputtered or electroplated. In the illustrated embodiment, an insulating layer 101 is provided on the backside of the substrate. A through substrate via 106 is also provided that ensures continuity from the top of the substrate 102 to the bottom surface.

Next, as shown in FIG. 4, the MEMS/NEMS layer 105 is selectively patterned using lithography and etched anisotropically using oxygen plasma RIE to define a trench 111 outside of the MEMS/NEMS device area. The trench 110 may be etched using DRIE Bosch process and may be lithographically defined by the size of chips 114. The etch so performed is stopped by the insulating layer 101. In a next step, the chip 114 of CMOS, MEMS/NEMS or a combination of them may be placed in the trench 110 such that the top side of the chip is facing towards insulating layer 101. The chip 114 is inserted in a manner that the bottom side is facing outwards to the substrate. As described above, a CMOS integrated chip may include voltage comparators, diodes, op-amps, or other electronic components like power management circuits, resistors, capacitors, and wireless modules including inductors. A MEMS/NEMS dies may include active sensing layer 109 but are not limited to accelerometers, resonators, micro-gyroscopes, microphones, micro-bolometers, transducers involving chemical and biological, optical, mechanical, radiation, thermal, capacitive, rotation, strain, magnetic and electromagnetic, flow, and micro-fluidic chemical properties of liquids and gases

In a following step, as shown in FIG. 5, a filler layer 112 may be deposited or dispensed into the trench 110 to anchor the chip 114 into the cavity and also to fill a gap between the chip 114 and the wall of the trench 110 and will also ensure the planarity of the chip 114 to the substrate 102. The filler material 112 may be selected from oxides, polyimides, silicones, epoxies, or their combination or any other materials with similar properties.

In a following step as shown in FIG. 6, post fabrication step of Anisotropic etch 191 followed by a isotropic etch 192 is performed to release and make the structure 105 free standing.

In a next step as shown in FIG. 7, a metallization layer 120 may be applied to connect the MEMS/NEMS on the semiconductor substrate 102 to the chip 114 which may include a contact area having an input/output pad or bond area to make electrical contact using through substrate via 106 and the via area 122 opened subsequently on 106. The metallization layer 120 may be selected from metals such as, aluminum, copper, titanium, chrome, gold, silver, iridium or their combination that can be evaporated, sputtered or electroplated. A person of ordinary skill in this art will be able to easily make further alterations and modifications in packaging after reading the present invention. It can easily be inferred that any particular embodiment illustrated with diagrams and explained cannot be considered limiting. For example the metallization layer 120 may include multiple layers sandwiched between multiple insulating layers connecting multiple devices and/or multiple chips on the substrate. The portion of the free standing structure 105 is protected by encapsulating using a metal or glass cap 125 as shown in FIG. 8.

All patents and publications mentioned in the prior art are indicative of the levels of those skilled in the art to which the invention pertains. All patents and publications are herein incorporated by reference to the same extent as if each individual publication was specifically and individually indicated to be incorporated by reference, to the extent that they do not conflict with this disclosure.

While the above examples provide a description of the process of the present invention, they should not be read as limiting the process of the present invention. The invention has been described in an illustrative manner. It is to be understood that the terminology which has been used is intended to be in the nature of words of description rather than limitation. Many modifications and variations of the invention are possible in light of the above teachings. Therefore, within the scope of the appended claims, the invention may be practiced other than as specifically described.

We claim:

1. A method of forming a monolithic CMOS-MEMS hybrid integrated, packaged device comprising the steps of:
providing a semiconductor substrate;
forming MEMS or NEMS materials on the substrate having conductive, structural, or dielectric layers;
forming at least one opening(s) on the semiconductor substrate;
positioning on the substrate at least one prefabricated MEMS, NEMS, or semiconductor chip(s), wherein the chip(s) comprise a side facing the substrate;
applying at least one filler material(s) in the opening(s) on the semiconductor substrate;
applying at least one metallization layer electrically connecting chip(s) to the MEMS or NEMS materials; and
performing at least one micro or nano fabrication etching step to remove a portion of the MEMS or NEMS materials.

2. The method of claim 1, wherein the MEMS or NEMS materials include structures selected from the group consisting essentially of: accelerometers, resonators, micro-gyroscopes, microphones, micro-bolometers, transducers involving chemical and biological properties, optical sensors, mechanical sensors, radiation sensors, thermal sensors, capacitive sensors, rotation sensors, strain sensors, magnetic and electromagnetic sensors, flow sensors, and sensors for micro-fluidic chemical properties of liquids and gases.

3. The method of claim 1, wherein the structural layer comprises polysilicon with a conductive area which is doped and annealed.

4. The method of claim 1, wherein the forming at least one opening(s) step comprises etching with Deep Reactive Ion Etching (DRIE).

5. The method of claim 1, wherein the filler layer is selected from the group consisting essentially of epoxies, polyimides, SUB, and polymers.

6. The method of claim 1, wherein the at least one chip is selected from the group consisting essentially of CMOS integrated circuits, electronics, amplifier dies, analog to digital converters, Radio Frequency (RF) circuits, optical chips, memory, power management circuits, GaAs chips, passive components, MEMS or NEMS sensors, and MEMS or NEMS dies.

7. The method of claim 6 wherein the MEMS or NEMS dies comprise accelerometers, resonators, micro-gyroscopes, microphones, micro-bolometers, transducers involving chemical and biological properties, optical sensors, mechanical sensors, radiation sensors, thermal sensors, capacitive sensors, rotation sensors, strain sensors, magnetic and electromagnetic sensors, flow sensors, and sensors for micro-fluidic chemical properties of liquids and gases.

8. The method of claim 1, wherein the metallization layer can be evaporated, sputtered or electroplated and is selected from the group consisting essentially of aluminum, titanium, chrome, gold or platinum or a combination of the same.

9. The method of claim 1, wherein the micro or nano fabrication etching step is selected from the group consisting essentially of wet, dry, isotropic, and anisotropic etching.

10. A monolithic CMOS-MEMS hybrid integrated, packaged device prepared in accordance with the method of claim 1.
